(19) United States
(12) Patent Application Publication
(10) Pub. No.: US 2012/0313158 A1
(43) Pub. Date: Dec. 13, 2012

(54) SEMICONDUCTOR STRUCTURE AND METHOD FOR MANUFACTURING THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignees: BEIJING NMC CO., LTD., Beijing (CN); Institute of Microelectronics, Chinese Academy of Sciences, Beijing (CN)

(21) Appl. No.: 13/380,666

(22) PCT Filed: Aug. 25, 2011
(86) PCT No.: PCT/CN2011/078922

§ 371 Date: Dec. 23, 2011

(30) Foreign Application Priority Data
Jun. 9, 2011 (CN) 201110154424.X

(51) Int. Cl. H01L 21/28; H01L 29/788; H01L 29/792; B82Y 99/00; B82Y 40/00

(52) U.S. Cl. 257/316; 438/591; 438/593; 257/324; 977/755; 257/E29.3; 257/E29.309; 257/E21.209; 257/E21.21

(57) ABSTRACT

The present invention provides a semiconductor structure and a method for manufacturing the same. The method comprises: providing a substrate, forming sequentially a first high-k dielectric layer, an adjusting layer, a second high-k dielectric layer and a metal gate on the substrate, etching the first high-k dielectric layer, the adjusting layer, the second high-k dielectric layer and the metal gate to form a gate stack. Accordingly, the present invention further provides a semiconductor structure. The present invention proposes to arrange an adjusting layer between two layers of high-k dielectric layer, which effectively avoids reaction of the adjusting layer with the metal gate because of their direct contact, so as to maintain the performance of semiconductor devices.

The present application claims priority benefit of Chinese Patent application No. 201110154424.X titled “Semiconductor Structure and Method for Manufacturing the Same” filed on 9 Jun. 2011, which is herein incorporated by reference in its entirety.

### FIELD OF THE INVENTION

The present invention relates to semiconductor manufacturing field, particularity, to a semiconductor structure and a method for manufacturing the same.

### BACKGROUND OF THE INVENTION

With development in the semiconductor manufacturing filed, integrated circuits with better performance and more powerful functions require greater element density, and the size of and the space between the components have to be further scaled down. Accordingly, the requirements for process control during manufacturing semiconductor devices become increasingly strict.

The application of the core technology at 22 nm or below for integrated circuits is an inevitable trend in developing integrated circuits and also is a hot spot, which major international semiconductor companies and research institutions are competitively endeavoring to make breakthrough. Due to poly-silicon depletion effect, high gate resistance and penetration of dopant ions shall arise from the use of poly-silicon electrodes, high-k dielectric layers and metal gate electrodes are widely applied nowadays in manufacturing of semiconductor devices, thereby producing semiconductor devices of high efficiency. The semiconductor device gate engineering with its focus on “high-k gate dielectric/metal gate” technology is the most representative and critical core process in the technology at 22 nm or below. Accordingly, researches on related materials, processes and structures are widely undertaken nowadays.

In addition to guaranteeing the same Equivalent Oxide Thickness (EOT), the use of high-k gate dielectric is able to increase physical thickness of the gate dielectric, such that the tunneling current is suppressed effectively. The introduction of metal gate electrodes not only overcomes the problems such as depletion effect of poly-silicon gate electrodes and penetration of dopant ions, but also effectively reduces resistance of gate electrodes and solves the problem of incompatibility between high-k gate materials and poly-silicon gates.

However, threshold voltages have to be controlled precisely in semiconductor devices of low power consumption. With operation voltages reduced to below 2V, threshold voltages have to be lowered accordingly, which renders threshold voltage fluctuations intolerable. Every new component, for example, a different gate dielectric or a different gate material, shall affect the threshold voltage. Sometimes, such an effect is not favorable for reaching a desired threshold voltage. Therefore, in the prior art, an adjusting layer is applied between a high-k dielectric layer and a metal gate to adjust the threshold voltage.

However, since the adjusting layer in the prior art is always arranged in direct contact with the gate conductor, although effective adjustment of the threshold voltage of devices may be achieved, reaction with the metal gate may not be avoided.

### SUMMARY OF THE INVENTION

The present invention aims to provide a semiconductor structure and a method for manufacturing the same, which effectively separates a gate metal from an adjusting layer, and avoids reaction of the adjusting layer with the metal that impairs performance of semiconductor devices.

In one aspect, the present invention provides a method for manufacturing a semiconductor structure, comprising:
(a) providing a substrate, forming sequentially a first high-k dielectric layer, an adjusting layer, a second high-k dielectric layer and a metal gate on the substrate;
(b) etching the first high-k dielectric layer, the adjusting layer, the second high-k dielectric layer and the metal gate to form a gate stack.

Accordingly, in another aspect, the present invention provides a semiconductor structure comprising a substrate and a gate stack, wherein the gate stack is formed on the substrate, and the gate stack sequentially comprises: a first high-k dielectric layer in contact with the substrate, an adjusting layer, a second high-k dielectric layer and a metal gate.

As compared to the prior art, the semiconductor structure and the method for manufacturing the same provided by the present invention exhibit following advantages: at formation of a gate, an adjusting layer is arranged between a first high-k dielectric layer and a second high-k dielectric layer, which effectively separates the adjusting layer from the metal gate. In the prior art, an adjusting layer is introduced for the purpose of adjusting the threshold voltages of the devices. Although the adjusting layer functions as stated above, it reacts with a metal gate because of its direct contact with the metal gate, which unfavorably impairs performance of the devices. Contrarily, a high-k dielectric layer is applied in the present invention to separate the adjusting layer from the metal gate, which effectively avoids impairment to the performance of devices arising from reaction of the adjusting layer with the metal gate. Meanwhile, although two high-k dielectric layers are used in the present invention, the total thickness of the two high-k dielectric layers is same as or close to the thickness of a single high-k dielectric layer used in conventional semiconductor structures, thus the entire dimension of a device is not increased. Obviously, such a technology follows the developing trend of increasing integration level but downscaling dimension of devices.

### BRIEF DESCRIPTION OF THE DRAWINGS

Other characteristics, objectives and advantages of the present invention are made more evident according to perusal of the following detailed description of exemplary embodiment(s) in conjunction with accompanying drawings.

FIG. 1 illustrates a flowchart of a method for manufacturing a semiconductor structure according to an embodiment of the present invention;

FIGS. 2 to 6 illustrate cross-sectional structural diagrams of a semiconductor structure at respective stages of the method for manufacturing a semiconductor structure according to the embodiment of the present invention as shown in FIG. 1;

Same or similar reference signs in the accompanying drawings denote same or similar elements.

### DETAILED DESCRIPTION OF THE INVENTION

Objectives, technical solutions and advantages of the present invention are made more evident according to the following detailed description of exemplary embodiments in conjunction with the accompanying drawings.

Embodiments of the present invention are described in detail below, wherein examples of the embodiments are illustrated in the drawings, in which same or similar reference signs throughout denote same or similar elements or elements have same or similar functions. It should be appreciated that the embodiments described below in conjunction with the drawings are illustrative, and are provided for explaining the prevent invention only, thus shall not be interpreted as limitations to the present invention.

Various embodiments or examples are provided below to implement different structures of the present invention. To simplify the disclosure of the present invention, description of components and arrangements of specific examples is given below. Of course, they are illustrative only and not intended to limit the present invention. Moreover, in the present invention, reference numbers and/or letters may be repeated in different embodiments. Such repetition is for the purpose of simplification and clearness, yet does not denote the relationship between respective embodiments and/or arrangements being discussed. Furthermore, the present invention provides various examples for various specific process and materials. However, it is obvious for a person of ordinary skill in the art that other processes and/or materials may alternatively be utilized. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It is to be noted that the component(s) illustrated in the drawings may not be drawn to scale. Description of conventional components, processing technology and crafts are omitted herein in order not to obscure the present invention unnecessarily.

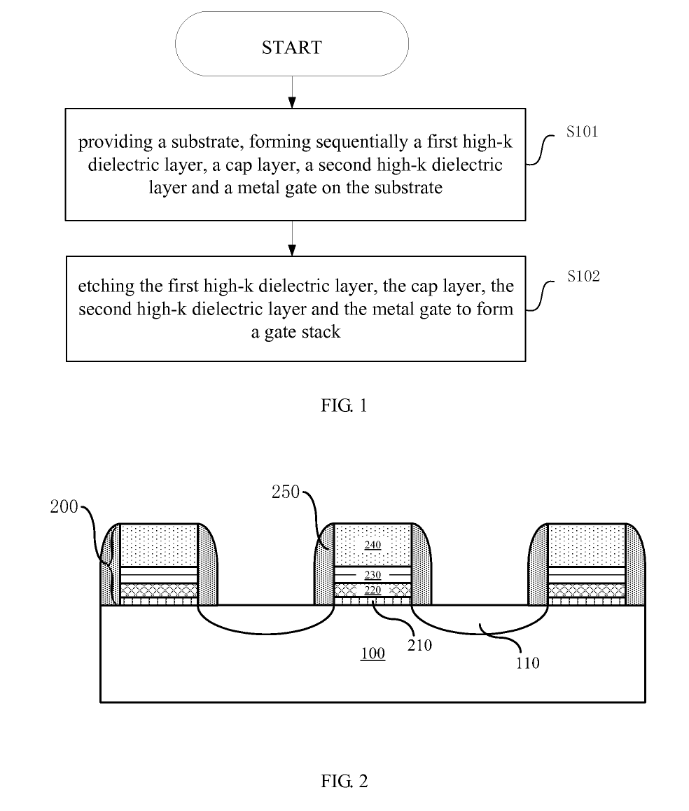

With reference to FIG. 1, which illustrates a flowchart of a method for manufacturing a semiconductor structure according to an embodiment of the present invention, the method comprising:

at step S101, providing a substrate 100, forming sequentially a first high-k dielectric layer 210, an adjusting layer 220, a second high-k dielectric layer 230 and a metal gate 240 on the substrate 100;

at step S102, etching the first high-k dielectric layer 210, the adjusting layer 220, the second high-k dielectric layer 230 and the metal gate 240 to form a gate stack 200.

Steps S101 and S102 are described here below in conjunction with FIGS. 2 to 6, which illustrate cross-sectional structural diagrams of a semiconductor structure at respective stages of the method for manufacturing a semiconductor structure according to the flowchart shown in FIG. 1, in view of various embodiments of the present invention. It should be noted that the drawings for respective embodiments are illustrative only, thus are not necessarily drawn to scale.

A substrate 100 is provided at step S101. As shown in FIG. 2, the substrate 100 comprises a silicon substrate (e.g. silicon wafer). According to the design requirement in the prior art (e.g. a P-type substrate or an N-type substrate), the substrate 100 may be of various doping configurations. The substrate 100 in other embodiments may further include other basic semiconductor, for example germanium. Alternatively, the substrate 100 may include a compound semiconductor, such as SiC, GaAs, InAs or InP. Typically, the substrate 100 may have, but is not limited to, a thickness of around several hundred micrometers, which for example may be in the range of 400 μm-800μm.

Optionally, while source/drain regions 110 may be formed after formation of a gate stack 200, source/drain regions 110 also may be built on the substrate 100 in advance. The source/drain regions 110 may be formed through implanting P-type or N-type dopants or impurities into the substrate 100. For example, the source/drain regions 110 may be P-type doped SiGe for a PMOS, while the source/drain regions 110 may be N-type doped Si for an NMOS. The source/drain regions 110 may be formed by means of lithography, ion implantation, diffusion, epitaxial growth and/or other method as appropriate, and may be formed prior to the formation of a first high-k dielectric layer 210. In the present embodiment, the source/drain regions 110 are located within the substrate 100, whereas in other embodiments, the source/drain regions 110 may be raised source/drain structures formed by means of selective epitaxial growth, wherein the top surfaces of the epitaxial portions are higher than the bottom of the gate stack (herein, the bottom of the gate stack indicates the boundary between the gate stack and the semiconductor substrate 100).

A first high-k dielectric layer 210 is deposited on the semiconductor substrate 100. The first high-k dielectric layer 210 located on the semiconductor substrate 100 is formed with, for example, any one of HfAlON, HfSiAlON, HfTaAlON, HfTiAlON, HfON, HfSiON, HfTaON, and HfTiON, or combinations thereof. The thickness of the first high-k dielectric layer 210 may be about 1 nm˜3 nm, for example 1.5 nm or 2 nm.

An adjusting layer 220 is formed on the first high-k dielectric layer 210. The material for the adjusting layer 220 comprises, but is not limited to, any one of Al, Al₂O₃ and La₂O₃, or combinations thereof. Its thickness is less than 0.5 nm, which is preferably less than 0.4 nm. Sputtering process is usually applied to deposit the adjusting layer 220. Unlike Chemical Vapor Deposition (CVD) or Atom Layer Deposition (ALD), the sputtering process needs no gas source but a metal sputtering target only. However, since sputtering is prone to cause damage to the exposed dielectric layer, Atom Layer Deposition is usually further applied to grow a material for the adjusting layer 220, for example La₂O₃.

A second high-k dielectric layer 230 is formed on the adjusting layer 220. The material for the second high-k dielectric layer 230 comprises, but is not limited to, for example, any one of HfAlON, HfSiAlON, HfTaAlON, HfTiAlON, HfON, HfSiON, HfTaON, and HfTiON, or combinations thereof. The thickness of the second high-k dielectric layer 230 may be about 2 nm˜3 nm, for example 2.3 nm or 3 nm.

The total thickness of the first high-k dielectric layer 210 and the second high-k dielectric layer 230 may be about 3 nm˜6 nm. Preferably, the first high-k dielectric layer 210 and the second high-k dielectric layer 230 are made of a same material.

A metal gate 240 is formed. For example, a metal gate 240 is formed through depositing any one of TaN, TaC, TiN, TaAlN, TiAlN, MoAlN, TaTbN, TaErN, TaYbN, TaSiN, HfSiN, MoSiN, RuTaₓ and NiTaₓ, or combinations thereof, on the second high-k dielectric layer 230. Its thickness may be about 10 nm˜80 nm, for example 30 nm or 50 nm.

At step S102, the metal gate 240, the second high-k dielectric layer 230, the adjusting layer 220 and the first high-k dielectric layer 210 are etched to form a gate stack 200, wherein the etching may be dry etching or wet etching. The dry etching includes plasma etching, ion milling, bombardment, reactive ion etching, while the wet etching includes etching with solutions of hydrofluoric acid, phosphoric acid and the like.

Optionally, sidewall spacers 250 are formed on sidewalls of the gate stack 200 to protect the gate. The sidewall spacers 250 may be formed with Si₃N₄, SiO₂, Si₂N₂O, SiC or a combination thereof, and/or other material as appropriate. The sidewall spacers 250 may be in a multi-layer structure and may be formed by means of a process including depositing and etching.

Next, an interlayer dielectric layer 300, which covers the source/drain regions 110, the gate stack 200 and the sidewall spacers 250, may be formed on the substrate 100. The interlayer dielectric layer 300 also fills the spaces around the gate stack 200. The interlayer dielectric layer 300 may be formed on the substrate 100 by means of Chemical Vapor Deposition (CVD), High-density Plasma CVD, spin coating or other method as appropriate. The material for the interlayer dielectric layer 300 may include SiO₂, carbon doped SiO₂, BPSG, PSG, UGS, Si₂N₂O, a low-k material or a combination thereof. The thickness of the interlayer dielectric layer 300 may be in the range of about 40 nm˜150 nm, for example, 80 nm, 100 nm or 120 nm.

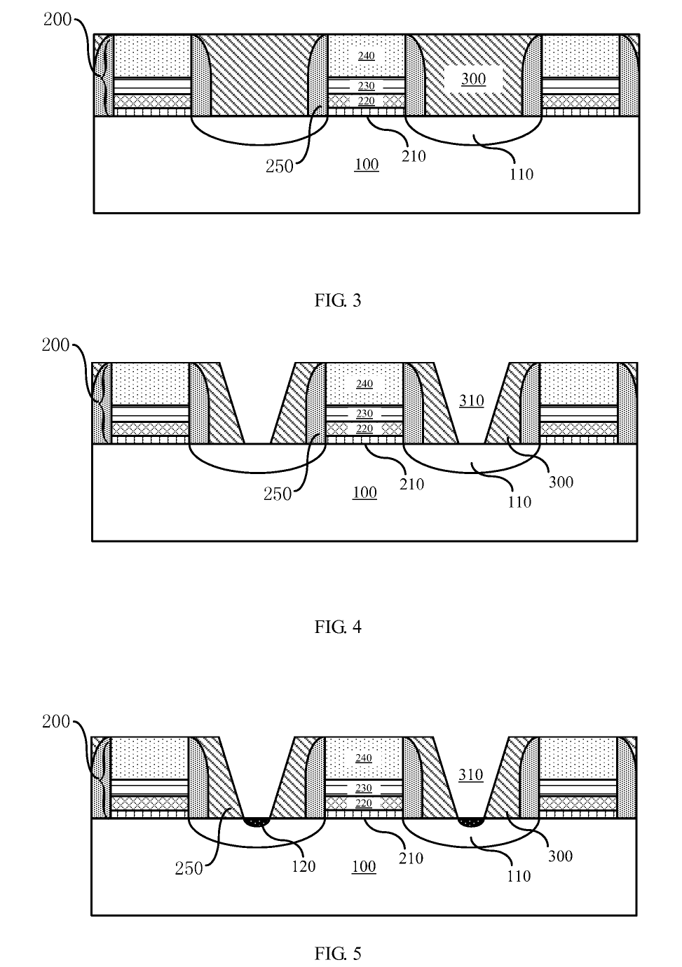

In the present embodiment, planarization treatment is performed to the interlayer dielectric layer 300 and the gate stack 200 on the semiconductor device by means of Chemical-Mechanical Polish (CMP), as shown in FIG. 3, such that the upper surface of the gate stack 200 becomes at the same level as the upper surface of the interlayer dielectric layer 300, and the top surfaces of the gate stack 200 and the sidewall spacers 250 are exposed.

Aforesaid method forms the gate stack of the present invention through Gate-First process. According to another embodiment of the present invention, the gate stack 200 of the present invention also may be formed by means of Gate-Last process.

For example, a dummy gate may be formed first, wherein for example the method for forming the dummy gate may comprises: first, forming a gate dielectric layer on a substrate, in the present embodiment, the gate dielectric layer may be formed with SiO₂, Si₃N₄ or a combination thereof, while it may be formed with a high-k dielectric in other embodiments, for example, any one of HfO₂, HfSiO, HfSiON, HfTaO, HfTiO, HfZrO, Al₂O₃, La₂O₃, ZrO₂ and LaAlO, or combinations thereof, and its thickness may be about 2-10 nm; then, forming a dummy gate on the gate dielectric layer through depositing poly-silicon, poly-SiGe, amorphous silicon, and/or doped or undoped SiO₂, Si₃N4, Si₂N₂O, SiC or even a metal, and its thickness may be about 10-80 nm; finally, forming an overlying layer on the dummy gate through, for example, depositing Si₃N₄, SiO₂, Si₂N₂O, SiC or a combination thereof, for the purpose of protecting the top surface of the dummy gate. In another embodiment, it is applicable not to incorporate a gate dielectric layer into the dummy gate stack. Instead, a gate dielectric layer shall not be formed until removal of the dummy gate stack in the subsequent Gate Replacement process.

The dummy gate is removed after formation of the source/drain regions 110. Besides, a first high-k dielectric layer 210, an adjusting layer 220, a second high-k dielectric layer 230 and a metal gate 240 are deposited sequentially at the place where the dummy gate is used to be, so as to form a gate stack 200.

Optionally, contact vias 320 may be further formed on the semiconductor structure, with reference to FIGS. 4-6. As shown in FIG. 4, the interlayer dielectric layer 300 is etched to form through holes 310, via which the source/drain regions 110 on the substrate are at least partly exposed. Specifically, the interlayer dielectric layer 300 may be etched to form the through holes 310 by means of dry etching, wet etching or other method as appropriate. The source/drain regions 110 in the substrate 100 are exposed after formation of the through holes 310. Because the gate stack 200 is protected by the sidewall spacers 250, even if over-etching happens during formation of the through holes 310, no short circuit shall arise between the gate and source/drain. In case that the source/drain regions 110 are raised source/drain structures formed by means of selective epitaxial growth, and the top surfaces of the epitaxial portions are higher than the bottom of the gate stack 200, the through holes 310 may be formed as deep as locations inside the source/drain regions 110 that are at the same level as the bottom of the gate stack 200. In this way, when contact vias 320 are formed through filling the through holes 310 with a contact metal, the contact metal shall be in contact with the source/drain regions 110 via the bottom and a portion of the sidewalls of the through holes, which therefore further increases the contact area and reduces the contact resistance.

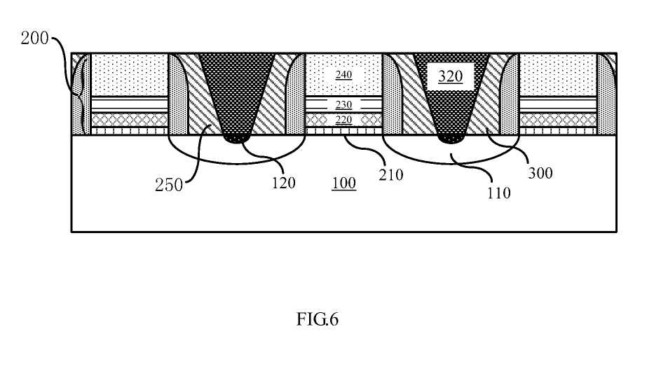

As shown in FIG. 5, the exposed source/drain regions 110 are located at the bottoms of the through holes 310. A metal is deposited on the source/drain regions 110 and is annealed to form metal silicide 120. Specifically, pre-amorphization treatment is performed to the exposed source/drain regions 110 by way of implanting ions, depositing an amorphous compound or selectively growing via the through holes 310, so as to form a partial amorphous silicon region. Then, a uniform metal layer is formed on the source/drain regions 110 by means of metal sputtering or Chemical Vapor Deposition. Preferably, the metal is Ni. Of course, the metal also may be other metal as appropriate, for example, Ti, Co or Cu. Then, the semiconductor structure is annealed. Other annealing processes, such as rapid thermal annealing and spike annealing, may be applied in other embodiments. According to embodiments of the present invention, a device is usually annealed by means of transient annealing process, for example, laser annealing at about 1000° C. for a period of microseconds, so as to enable the deposited metal to react with the amorphous compound formed within the source/drain regions 110 to form metal silicide 120. Finally, the deposited metal that remains from reaction may be removed through chemical etching. The amorphous compound may be any one of amorphous silicon, amorphous SiGe and amorphous SiC. The benefit of forming the metal silicide 120 is to lower resistivity between the contact metal within the contact vias 320 and source/drain regions 110, so as to further reduce the contact resistance.

It should be noted that the step of forming the metal silicide 120 shown in FIG. 5 is a preferred step. Namely, it is applicable not to form metal silicide 120 but to fill the through holes 310 directly with a contact metal, so as to form the contact vias 320.

As shown in FIG. 6, contact vias 320 are formed through filling a contact metal into the through holes 310 by means of deposition. The contact metal has a lower portion that is electrically connected with the exposed source/drain regions 110 within the substrate 100 (the term “electrically connected” indicates that the lower portion of the contact metal may be in direct contact with the exposed source/drain regions 110 within the substrate 100, or in essence may be electrically connected with the exposed source/drain regions 110 within the substrate via the metal silicide 120 formed on the exposed source/drain regions 110 within the substrate 100). The contact metal extends through the interlayer dielectric layer 300 via the through holes 310 and exposes its top surface.

Preferably, the material for the contact metal is W. Of course, the material for the contact metal comprises, but is not limited to, any one of W, Al and TiAl alloy, or combinations thereof, according to the needs of manufacturing a semiconductor in practice. Optionally, prior to filling the contact metal, a lining layer (not shown) may be selectively formed on the interior sidewalls and the bottoms of the through holes 310. The lining layer may be formed on the interior sidewalls and the bottoms of the through holes 310 by means of ALD, CVD, PVD or the like. The material for the lining layer may be Ti, TiN, Ta, TaN, Ru or a combination thereof. The thickness of the lining layer may be about 5 nm-20 nm, for example, 10 nm or 15 nm.

Then, the semiconductor device is finished according to the steps of the conventional semiconductor manufacturing process.

In order to give a clearer picture of the semiconductor structure manufactured according to aforesaid method for manufacturing a semiconductor structure, the semiconductor structure is described here below in conjunction with FIG. 6.

As shown in FIG. 6, the semiconductor structure comprises: a substrate 100; a gate stack 200 formed on the substrate 100 and sequentially comprising a first high-k dielectric layer 210 in contact with the substrate 100, an adjusting layer 220, a second high-k dielectric layer 230 and a metal gate 240; sidewall spacers 250 formed on sidewalls of the gate stack 200; source/drain regions 110 formed on two sides of the gate stack 200; an interlayer dielectric layer 300; contact vias 320 extending through the interlayer dielectric layer 300.

In an embodiment, the source/drain regions 110 may be raised source/drain structures. Namely, the top surfaces of the source/drain regions 110 are higher than the bottom of the gate stack 200. In this case, the bottoms of the through holes 310 is at the same level as the bottom of the gate stack 200.

The first high-k dielectric layer 210 located on the semiconductor substrate 100 is formed with, for example, any one of HfAlON, HfSiAlON, HfTaAlON, HfTiAlON, HfON, HfSiON, HfTaON and HfTiON, or combinations thereof; the thickness of the first high-k dielectric layer 210 may be about 1 nm˜3 nm, for example 1.5 nm or 2 nm.

An adjusting layer 220 is arranged between the first high-k dielectric layer 210 and the second high-k dielectric layer 230. The material for the adjusting layer 220 comprises, but is not limited to, any one of Al, Al₂O₃ and La₂O₃, or combinations thereof. Its thickness may be less than 0.5 nm, for example, 0.4 nm or 0.3 nm. The adjusting layer 220 may be formed by means of sputtering process and Atom Layer Deposition (ALD).

The second high-k dielectric layer 230 is located on the adjusting layer 220. The material for the second high-k dielectric layer 230 comprises, but is not limited to, for example, any one of HfAlON, HfSiAlON, HfTaAlON, HfTiAlON, HfON, HfSiON, HfTaON and HfTiON, or combinations thereof. The thickness of the second high-k dielectric layer 230 may be about 2 nm˜3 nm, for example, 2.3 nm or 3 nm.

The total thickness of the first high-k dielectric layer 210 and the second high-k dielectric layer 230 may be about 3 nm˜6 nm. Preferably, the first high-k dielectric layer 210 and the second high-k dielectric layer 230 are made of a same material.

In order to control the depth of the through holes 310 in the source/drain regions 110, an etch stop layer may be reserved at formation of the source/drain regions 110. The material for the etch stop layer is different from the material for other portions of the source/drain regions 110. When the through hole 310 are formed through etching, the through holes 310 goes no further than the etch stop layer. In case that the source/drain regions 110 are raised source/drain structures, the position of the etch stop layer is preferably at the same level as the bottom of the gate stack 200. Preferably, the material for the etch stop layer is Si. The portion of the source/drain regions 110 above the etch stop layer is made of SiGe.

According to implementation of the method for manufacturing a semiconductor structure provided by the present invention, the high-k dielectric layer is separated into two pieces, i.e., a first high-k dielectric layer 210 and a second high-k dielectric layer 230, between which an adjusting layer 220 is arranged. In this way, the adjusting layer 220 is effectively safeguarded from direct contact with a metal gate 240, thus reaction of the adjusting layer 220 with the metal gate 240 is avoided.

Although exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising:
providing a substrate; and
forming a gate stack on the substrate,
wherein the gate stack comprises a first high-k dielectric layer, an adjusting layer, a second high-k dielectric layer and a metal gate sequentially from the substrate.

2. The method of claim 1, wherein the adjusting layer is formed by means of sputtering, Chemical Vapor Deposition or Atom Layer Deposition.

3. The method of claim 1, wherein the material for the adjusting layer comprises any one of Al, Al₂O₃ and La₂O₃, or combinations thereof.

4. The method of claim 1, wherein the thickness of the adjusting layer is less than 0.5 nm.

5. The method of claim 1, wherein the total thickness of the first high-k dielectric layer and the second high-k dielectric layer is in the range of about 3 nm˜6 nm.

6. The method of claim 1, wherein the thickness of the first high-k dielectric layer is in the range of about 1 nm˜3 nm.

7. The method of claim 1, wherein the thickness of the second high-k dielectric layer is in the range of about 2 nm˜3 nm.

8. A semiconductor structure, which comprises a substrate and a gate stack, wherein:
the gate stack is formed on the substrate and sequentially comprises: a first high-k dielectric layer in contact with the substrate, an adjusting layer, a second high-k dielectric layer and a metal gate.

9. The semiconductor structure of claim 8, wherein the material for the adjusting layer comprises any one of Al, Al₂O₃ and La₂O₃, or combinations thereof.

10. The semiconductor structure of claim 8, wherein the thickness of the adjusting layer is less than 0.5 nm.

11. The semiconductor structure of claim 8, wherein the total thickness of the first high-k dielectric layer and the second high-k dielectric layer is in the range of about 3 nm˜6 nm.

12. The semiconductor structure of claim 8, wherein the thickness of the first high-k dielectric layer is in the range of about 1 nm˜3 nm.

13. The semiconductor structure of claim 8, wherein the thickness of the second high-k dielectric layer is in the range of about 2 nm˜3 nm.
